(19) United States
(12) Patent Application Publication
(10) Pub. No.: US 2025/0015148 A1
(43) Pub. Date: Jan. 9, 2025

(54) TRANSISTOR DEVICE

(71) Applicant: Infineon Technologies AG, Neubiberg (DE)

(72) Inventors: Thomas AICHINGER, Faak am See (AT); Wolfgang BERGNER, Klagenfurt am Wörthersee (AT); Hans WEBER, Villach (AT); Michael HELL, Erlangen (DE); Armin TILKE, Dresden (DE); Grazvydas ZIEMYS, München (DE)

(21) Appl. No.: 18/764,822

(22) Filed: Jul. 5, 2024

(30) Foreign Application Priority Data
Jul. 6, 2023 (DE) 102023117853.9

(51) Int. Cl. H01L 29/40; H01L 29/06; H01L 29/16; H01L 29/423; H01L 29/66; H01L 29/78

(52) U.S. Cl. CPC H01L 29/407; H01L 29/0696; H01L 29/1608; H01L 29/4236; H01L 29/66068; H01L 29/66734; H01L 29/7813

(57) ABSTRACT

A transistor device and a method for manufacturing a transistor device are disclosed. The transistor device includes a semiconductor body and a plurality of transistor cells. Each transistor cell includes: a drift region, a body region, and a source region; a gate electrode connected to a gate node; and a field electrode connected to a source node. The gate electrode is dielectrically insulated from the body region by a gate dielectric, and is arranged in a first trench extending from a first surface into the semiconductor body. The field electrode is dielectrically insulated from the drift region by a high-k dielectric, and is arranged in a second trench. The second trench extends from the first surface into the semiconductor body and is spaced apart from the first trench, and the field electrode extends at least as deep as the first trench into the semiconductor body.

### RELATED APPLICATION

This application claims priority to German Patent Application No. 102023117853.9, filed on Jul. 6, 2023, entitled “TRANSISTOR DEVICE”, which is incorporated by reference herein in its entirety.

### TECHNICAL FIELD

This disclosure relates in general to a transistor device, in particular a silicon carbide (SiC) based transistor device.

### SUMMARY

Silicon carbide (SiC) has a higher bandgap than silicon (Si), so that SiC is capable of withstanding higher electric fields than silicon. Thus, in an SiC based vertical transistor device with a given voltage blocking capability the length of the drift region can be reduced as compared to a silicon based vertical transistor device with the same voltage blocking capability. The reduced length of the drift region results in a lower on-resistance of the SiC device as compared to the silicon device. The reduction of the on-resistance, which is the electrical resistance of the transistor device in the on-state results in lower conduction losses and is an ongoing goal in the design of transistor devices.

A vertical SiC transistor device can be implemented with trench gate electrodes, which are gate electrodes that are arranged in trenches extending from a surface into a SiC semiconductor body. The trench gate electrodes are dielectrically insulated from the semiconductor body by a gate dielectric.

High electric fields that may occur in a SiC based transistor device may damage the gate dielectric. Conventional SiC based transistor devices therefore include doped regions of a doping type complementary to the doping type of the drift region and connected to a source node (source electrode) of the transistor device. These doped regions are located below the gate trenches and, together with the drift region, form a JFET that, in a blocking state of the transistor device, protects the gate dielectric from high electric fields.

Such doped regions, which may be referred to as JFET regions, can be formed using an implantation process. The implantation process for forming JFET regions, however, may be costly and require a thick implantation mask to be formed on top of the semiconductor body. Furthermore, due to a lateral straggling of implanted dopant atoms a reduction of the cell pitch is limited. The cell pitch is given by the center-to-center distance between neighboring gate trenches or neighboring JFET regions, for example. Furthermore, pn-junctions are formed between the drift region and the JFET regions. Such pn-junctions, even in an on-state of the transistor device, involve space-charge regions (depletion regions), which reduce a width of an electrically conducting path of the transistor device in the on-state. This limits the minimal possible cell pitch, even if perfectly shaped JFET regions would be possible.

There is therefore a need for an improved SiC based transistor device.

One example relates to a transistor device. The transistor device includes a semiconductor body and a plurality of transistor cells. Each transistor cell includes a drift region, a body region, and a source region, a gate electrode connected to a gate node, and a field electrode connected to a source node. The gate electrode is dielectrically insulated from the body region by a gate dielectric, and is arranged in a first trench extending from a first surface into the semiconductor body. The field electrode is dielectrically insulated from the drift region by a high-k dielectric, and is arranged in a second trench. The second trench extends from the first surface into the semiconductor body and is spaced apart from the first trench. Furthermore, the field electrode extends at least as deep as the first trench into the semiconductor body.

Another example relates to a method. The method includes forming a plurality of transistor cells in a semiconductor body such that each transistor cell includes a drift region, a body region, and a source region; a gate electrode connected to a gate node, dielectrically insulated from the body region by a gate dielectric, and arranged in a first trench extending from a first surface into the semiconductor body; and a field electrode connected to a source node, dielectrically insulated from the drift region by a high-k dielectric, and arranged in a second trench extending from the first surface into the semiconductor body and spaced apart from the first trench. Forming the field electrode of each transistor cell includes forming the field electrode such that the field electrode extends deeper into the semiconductor body than the first trench.

Examples are explained below with reference to the drawings. The drawings serve to illustrate certain principles, so that only aspects necessary for understanding these principles are illustrated. The drawings are not to scale. In the drawings the same reference characters denote like features.

### BRIEF DESCRIPTION OF THE DRAWINGS

FIG. 1 shows a vertical cross-sectional view of a transistor device with a plurality of transistor cells that each include a gate electrode arranged in a first trench of a semiconductor body and a field electrode arranged in a second trench and dielectrically insulated from a drift region by a high-k dielectric.

FIG. 2 shows a top view of the transistor device according to one example.

FIG. 3 shows a top view of the transistor device according to another example.

FIG. 4 shows a detailed review of one first trench and one neighboring second trench.

FIGS. 5-7 illustrate one example for connecting body regions of the transistor cells to a source electrode of the transistor device.

FIG. 8 illustrates another example for connecting the body regions to the source electrode.

FIG. 9 shows a top view of the semiconductor body and illustrates one example for connecting gate electrodes of the type illustrated in FIG. 2 to a gate pad of the transistor device.

FIGS. 10-13 illustrate various modifications of transistor cells of the type illustrated in FIG. 8.

FIGS. 14A-14D illustrate one example of a method for forming the high-k dielectric and the field electrodes in the second trenches.

FIGS. 15A-15C illustrate one example of a method for forming a source electrode on top of the semiconductor body.

FIGS. 16A-16H illustrate one example of a method for forming the gate dielectrics and the gate electrodes in the first trenches of the semiconductor body.

FIG. 17 illustrates one example of a method for forming a doped region along sidewalls of the second trenches.

FIGS. 18A-18B illustrates one example of a method for forming high-k dielectrics that are spaced apart in the second trenches from a first surface of the semiconductor body.

FIG. 19 illustrates one example of a method for forming a deep current spreading region.

FIG. 20 illustrates one example of a method for forming second trenches of the type illustrated in FIGS. 11 and 12.

FIG. 21 illustrates the voltage blocking capability of the transistor device dependent on a cell pitch and dependent on a relative dielectric constant of the high-k dielectric.

FIG. 22 illustrates the dielectric field in the gate dielectric dependent on the cell pitch.

FIG. 23 illustrates a vertical cross-sectional view of a transistor device according to another example.

### DETAILED DESCRIPTION

In the following detailed description, reference is made to the accompanying drawings. The drawings form a part of the description and for the purpose of illustration show examples of how the disclosed subject matter may be used and implemented. It is to be understood that the features of the various embodiments described herein may be combined with each other, unless specifically noted otherwise.

FIG. 1 shows a transistor device according to one example. More specifically, FIG. 1 shows a vertical cross-sectional view of one portion of the transistor device. The transistor device includes a semiconductor body 100 and a plurality of transistor cells 1. The semiconductor body 100 includes a first surface 101 and a second surface 102. The second surface 102 is opposite the first surface 101 and is spaced apart from the first surface 101 in a vertical direction z of the semiconductor body 100.

According to one example, the semiconductor body 100 is a monocrystalline semiconductor body. According to one example, the semiconductor body 100 includes monocrystalline silicon carbide (SiC). According to one example, the monocrystalline SiC is monocrystalline SiC of the 4H, 6H, or 3H polytype.

Implementing the semiconductor body 100 with monocrystalline SiC, however, is only an example. Other semiconductor materials, such as silicon (Si), may be used as well.

Referring to FIG. 1, each transistor cell includes a drift region 11, a body region 12, and a source region 13. Each of the drift region 11, the body region 12, and the source region 13 is a doped semiconductor region within the semiconductor body 100. According to one example, the body region 12 adjoins both the source region 13 and the drift region 11, wherein the body region 12 is arranged between the source region 13 and the drift region 11. The source region 13 of each transistor cell 1 is connected to a source node S. According to one example, not illustrated in FIG. 1, the body regions 12 of the transistor cells are also connected to the source node S.

In the following, body regions 12, source regions 13, and drift regions 11 are referred to as “active device regions”. According to one example, doping concentrations of the active device regions are selected from the following ranges, drift region 11: between 1E15 cm⁻³ and 1E17 cm⁻³; body region 12: between 1E16 cm⁻³ and 1E18 cm⁻³; source region 13: higher than 1E19 cm⁻³.

Furthermore, each transistor cell 1 includes a gate electrode 21 and a field electrode 31. The gate electrode 21 is arranged adjacent to the body region 12, is dielectrically insulated from the body region 12 by a gate dielectric 22, and is connected to a gate node G. Furthermore, the gate electrode 21 is arranged in a first trench 23 that, from the first surface 101, extends into the semiconductor body 100. According to one example, the gate electrode 21 essentially extends in the vertical direction z in the direction of the second surface 102. The first trench 23 is spaced apart from the second surface 102.

The field electrode 31 is arranged adjacent to the drift region 11, is dielectrically insulated from the drift region 11 by a field electrode dielectric 32, and is connected to the source node S. Furthermore, the field electrode 31 is arranged in a second trench 33 That is spaced apart from the first trench 21. The second trench 32, from the first surface 101, extends into the semiconductor body 100. According to one example, the field electrode 31 essentially extends in the vertical direction z in the direction of the second surface 102. The second trench 33 is spaced apart from the second surface 102.

According to one example, the gate electrodes 21 include a metal or a highly doped polycrystalline semiconductor material such as, for example, polysilicon. Equivalently, the field electrodes 31 may include a metal or a highly doped polycrystalline semiconductor material, such as polysilicon.

In the following, the first trench 23 is also referred to as gate trench. Furthermore, the second trench 33 is also referred to as field electrode trench.

In FIG. 1, the gate and source nodes G, S, connections between the gate electrodes 21 and the gate node G, connections between the field electrodes 31 and the source node S, and connections between source and body regions 13, 12 and the source node S are only schematically illustrated. The gate and source nodes may be implemented using conventional metallizations, and the connections be implemented using conventional wiring techniques. One example for implementing such circuit nodes and connections are explained herein further below.

Furthermore, in each transistor cell 1, the field electrode trench 33 including the field electrode 31 is spaced apart from the gate trench 23 including the gate electrode 21 in a lateral direction x of the semiconductor body 100. The lateral direction x is essentially perpendicular to the vertical direction z.

The field electrode 31 extends into the semiconductor body 100 at least as deep as the gate trench 23. That is, a dimension of the field electrode 31 in the vertical direction z of the semiconductor body 100 at least equals a dimension of the gate trench 23 in the vertical direction z. This is explained in detail herein further below with reference to FIG. 4.

The field electrode dielectric 32 is a high-k dielectric. According to one example, this includes that a relative dielectric constant K of the field electrode dielectric 32 is higher than the relative dielectric constant of silicon dioxide (SiO₂), which has a relative dielectric constant of about 3.9, K_{siO2}≈3.9. According to one example, the material of the field electrode dielectric 32 is selected such that the relative dielectric constant K of the field electrode dielectric 32 is higher than 5, higher than 10, higher than 20, or even higher than 30. The relative dielectric constant of the high-k dielectric may also be referred to as K factor.

Examples for implementing the field electrode dielectric 32 include, but are not restricted to, Al₂O₃ (aluminum oxide), ZrO₂ (zirconium oxide), HfO₂ (hafnium oxide) or silicon doped HfO₂, AlN (aluminum nitride), AlSiOₓ (aluminum silicate), TiO₂ (titanium oxide), Y₂O₃ (yttrium oxide), or Si₃N₄ (silicon nitride). The field electrode dielectric 32 may be comprised entirely of the same material, such as one of the materials explained before. According to another example, the field electrode dielectric 32 includes a layer stack with two or more different dielectric layers. At least one of these two or more layers may include one of the materials explained before. Another one of these two or more layers may include a low-k dielectric, such as SiO₂.

According to one example, the gate dielectric 22 includes silicon oxide (SiO₂). According to another example, the gate dielectric 22 includes a high-k dielectric. The material of the high-k dielectric may be in accordance with one of the examples explained with reference to the field dielectric 32 herein before.

According to one example, the drift and source regions 11, 13 are doped regions of a first doping type, and the body regions 12 are doped regions of a second doping type complementary to the first doping type. The transistor device can be implemented as an N-type transistor device or as a P-type transistor device. In an N-type transistor device, the drift and source regions 11, 13 are N-type regions and the body regions 12 are P-type regions. In a P-type transistor device, the drift and source regions 11, 13 are P-type regions and the body regions 12 are N-type regions. Furthermore, the transistor device can be implemented as an enhancement device are as a depletion device. In an enhancement device, the body region 12 of each transistor cell 1 adjoins the gate dielectric 22 of the respective transistor cell (as illustrated in FIG. 1). In a depletion device, each transistor cell 1, in addition to the body region 12, includes a channel region of the same doping type as the source region 13 between the body region 12 and the gate dielectric 22. Such channel region, however, is not illustrated in FIG. 1.

The transistor device according to FIG. 1 can be operated in a conventional way by applying a drive voltage (gate-source voltage) between the gate node G and the source node S. The transistor device is in an on-state (conducting state) when a drive voltage is applied between the gate node G and the source node S that, in each transistor cell 1, causes a conducting channel in the body region 12 along the gate dielectric 22 between the source region 13 and the drift region 11. An N-type transistor device, for example, is in the on-state when a positive drive voltage higher than the threshold voltage is applied between the gate and source nodes G, S.

In the on-state, a current can flow from the source node S via the source regions 13, the conducting channels in the body regions 12, and the drift region 11 to a drain node D. The drain node D, which is only schematically illustrated in FIG. 1, is electrically connected to the drift region 11 of each transistor cell 1. According to an example illustrated in dashed lines in FIG. 1, the drain node D is connected to the drift region 11 via a drain region 15. According to one example, the drain region 15 is of the same doping type as the drift region 11 and has a higher doping concentration. According to one example, the doping concentration of the drain region 15 is at least 100 times the doping concentration of the drift region 11.

In order to more evenly distribute the current in the drift region 11 when the transistor device is in the on-state, the drift region 11 may include a current spreading region 14. The current spreading region 14 is a portion of the drift region 11 and has a higher doping concentration than the remainder of the drift region 11. According to one example, the doping concentration of the current spreading region 14 is between 3 times and 100 times of the doping concentration of the remainder of the drift region 11.

In the example illustrated in FIG. 1, in each transistor cell 1, the current spreading region 14 adjoins the body region 12. This, however, is only an example. It is also possible to implement the current spreading region 14 in such a way that the current spreading region 14 is spaced apart from the body region 12 in the vertical direction z.

Referring to FIG. 1, the gate trenches 23 with the gate electrodes 21 may extend into the drift region 11. According to one example, as seen from the first surface 101, the current spreading region 14 extends deeper into the semiconductor body 100 in the vertical direction z than the gate trenches 23. As further illustrated in FIG. 1, the current spreading region 14 may extend less deep into the semiconductor body 100 than the field electrode trenches 33. This, however, is only an example. According to another example (not illustrated) the current spreading region 14 extends deeper into the semiconductor body 100 in the vertical direction z than the field electrode trenches 33, so that the current spreading region 14 surrounds bottoms of the field electrode trenches 33.

The transistor device is in the off-state when the conducting channels in the body regions 12 are interrupted. In the off-state, when a voltage is applied between the drain and source nodes D, S that reverse biases PN junctions between the body and drift regions 12, 11, space charge region (depletion region) expands in the drift region 11. Such depletion regions are associated with an electric field.

In a transistor device that is devoid of the field electrodes 31 of the type illustrated in FIG. 1, a maximum of the electric field occurs in the drift region 11 close to the PN junctions. If, for example, in the off-state, the electrical potential of the gate electrodes 21 equals the electrical potential of the source and body regions 13, 12, the electric field E₂₂ in the gate dielectric 22 in a center of a gate trench bottom (where the field lines of the electric field are essentially perpendicular to an interface between the drift region 11 and the gate dielectric 22) is essentially given by

$${E}_{22} = \frac{{ε}_{11}}{{ε}_{22}} \cdot {E}_{11} , \qquad ( 1 )$$

where ε₁₁ denotes the relative dielectric constant (K factor) of the semiconductor material of the semiconductor body 100, ε₂₂ denotes the relative dielectric constant (K factor) of the dielectric material of the gate dielectric 22, and E₁₁ denotes the magnitude of the electric field in the drift region 11 in a region adjoining the gate dielectric 22. The gate dielectric 22 may include silicon oxide (SiO₂), which has a relative dielectric constant of about 3.9. Silicon carbide, for example, has a relative dielectric constant of about 9.6. Thus, if the semiconductor material of the semiconductor body 100 includes silicon carbide and the gate dielectric 22 includes silicon oxide, in accordance with equation (1) the dielectric field E₂₂ in the silicon oxide may be significantly higher (about 2.5 times) than the dielectric field in the adjoining semiconductor material. This may have the effect that the electric field in the gate dielectric 22 may become higher than the critical electric field of the gate dielectric. This may result in a degradation or damaging of the gate dielectric 22.

The critical electric field of silicon carbide is between 2 MV/cm and 3 MV/cm. The critical electric field for intrinsic breakdown of silicon dioxide is between 8 MV/cm and 10 MV/cm, which is more than 2.5 times the critical electric field of silicon carbide. However, due to imperfections in the manufacturing process of the gate dielectric 22, the critical electric field of the gate dielectric 22 may be less than the theoretical critical electric field of the material used to implement the gate dielectric 22. Thus, in order to achieve a reliable device, the electric field in the dielectric layer separating the gate electrode 21 from the drift region 11 should be less than twice the critically electric field of the material of the semiconductor body 100 and/or considerably less than the theoretical breakdown limit of said dielectric layer.

In the transistor device 1 according to FIG. 1, the field electrodes 31 connected to the source node S, in the off-state of the transistor device, generate a space charge region (depletion region) in the drift region 11 in sections adjoining the field electrode dielectric 32. As the voltage applied between the drain and source notes D, S increases, this depletion region, beginning from the field electrode dielectric 32, extends deeper into the drift region 11 as seen from the field electrode dielectric 32.

According to one example, the field electrode 31 of each transistor cell 1 is implemented such that the field electrode 31 entirely depletes the drift region 11 in the region adjoining the gate dielectric 22 before the electric field, due to the increasing voltage between the drain and source notes D, S, reaches a magnitude that may damage the gate dielectric 21. In particular, the lateral distance between the first and second trenches 23, 33 and the vertical dimension of the field electrode 31 may be implemented in such a way that the field electrode 31 is capable of depleting the drift region 11 and the region around the gate dielectric 22.

Referring to the above, the field electrode dielectric 32 is a high-k dielectric. The critical electric field of the high-k dielectric may be lower than the critically electric field of a low-k dielectric, such as SiO₂. However, due to the high K factor, measured at the same field in the semiconductor drift region, the electric field in the field electrode dielectric 32 implemented with a high-k dielectric is lower than the electric field in a conventional field electrode dielectric including a low-k dielectric. Thus, the field electrode dielectric 32 including the high-k dielectric is more robust in view of electric fields occurring in the drift region 11 than the gate dielectric 22.

In FIG. 1, several transistor cells 1 of the transistor device are illustrated. As can be seen from FIG. 1, two (or more) transistor cells may share an active device region 11, 12, 13, a gate electrode 21 or a field electrode 31. In the example illustrated in FIG. 1, for example, the gate electrodes 21 of two neighboring transistor cells 1 are formed by the same trench electrode. Furthermore, the field electrodes 31 of two (other) neighboring transistor cells 1 are formed by the same trench electrode. Furthermore, as can be seen from FIG. 1, the drift regions 11 of the plurality of transistor cells may be formed by one and the same doped region of the semiconductor body 100. Equivalently, the drain regions 15 of the transistor cells 1 may be formed by one and the same doped region of the semiconductor body 100.

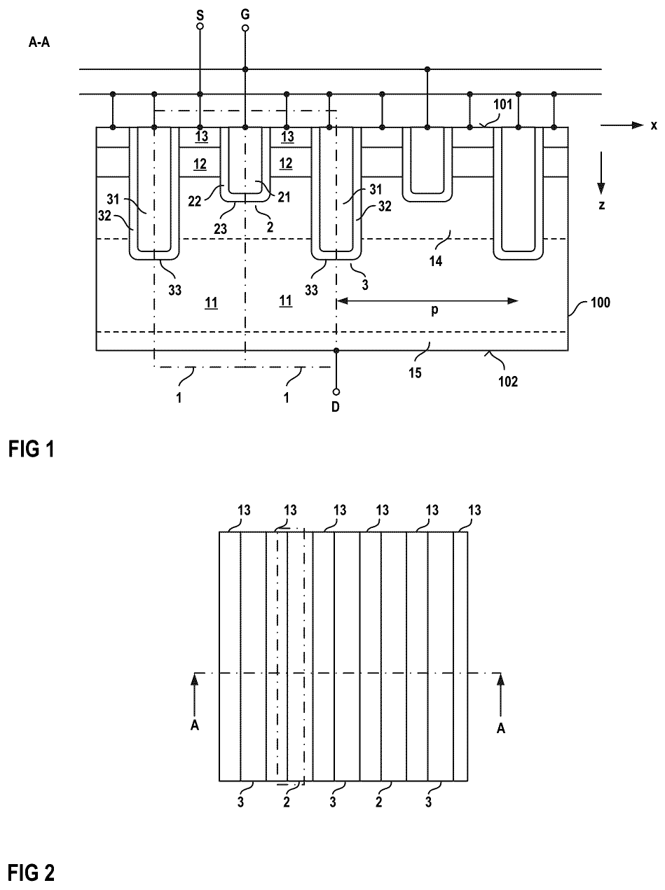

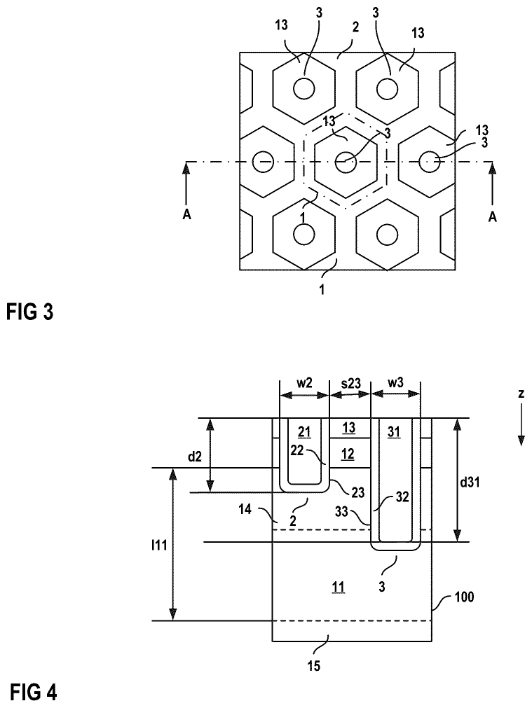

FIG. 1 shows a vertical cross-sectional view of several transistor cells 1. In a horizontal plane, which is a plane that is essentially parallel to the first and second surfaces 101, 102 and vertical to section plane A-A illustrated in FIG. 1, the transistor cells 1 may be implemented in various ways. Two different examples are explained with reference to FIGS. 2 and 3 in the following. In each of FIGS. 2 and 3, reference number 2 denotes gate structures that each include a gate electrode 21 and a gate dielectric 22, wherein the gate electrodes 21 and the gate dielectrics 22 are not explicitly illustrated in these figures. Furthermore, reference number 3 denotes field electrode structures that each include a field electrode 31 and a field electrode dielectric 32, wherein the field electrodes 31 and the field dielectrics 32 are not explicitly illustrated in these figures.

Referring to FIG. 2, the transistor cells 1 may be implemented as elongated transistor cells, which may also be referred to as stripe cells. In this example, the gate structures 2 (with the gate electrodes and the gate dielectrics) and the field electrode structures 3 (with the field electrodes and the field electrode dielectrics) are elongated in a horizontal (lateral) direction of the semiconductor body 100. Equivalently, the source regions 13 and the body regions 12 (which are out of view in FIG. 2) are elongated, wherein each source and body region 13, 12 is arranged between a gate structure 2 and a respective field electrode structure 3.

Referring to FIG. 3, the transistor cells 1 may be implemented as hexagonal transistor cells. In this example, the gate structure 2 (with the gate electrode and the gate dielectric) has the form of a hexagonal grid, wherein the source regions 13 and the body regions 12 (which are out of view in FIG. 3) are formed in hexagonal spaces defined by the hexagonal grid. In this example, each transistor cell 1 includes one field electrode structure 3 that has the shape of a needle or pile.

Referring to the above, the semiconductor body 100 may include monocrystalline SiC of the 4H polytype. In this example, the hexagonal gate structure 2 may be arranged within the crystal of the monocrystalline SiC semiconductor body such that the channel regions between the gate dielectrics 22 and the body regions 12 are aligned to match vertical crystal planes of the semiconductor body. This is beneficial in view of a reduction of the channel resistance.

It should be noted that implementing the transistor cells 1 as hexagonal transistor cells by implementing the gate structure as a hexagonal grid is only an example. Other shapes of the transistor cells 1, such as rectangular transistor cells by implementing the gate structure 2 as a rectangular grid, are possible as well.

FIG. 4 shows a vertical cross-sectional view of one portion of the transistor device in greater detail in order to explain some dimensions of the transistor cells 1. More specifically, the portion of the transistor device illustrated in FIG. 4 includes a first trench 23, a second trench 33, source and body regions 13, 12 arranged between the first and second trenches 23, 33, a portion of the drift region 11, a portion of the optional drain region 15, and a portion of the optional current spreading region 14. In FIG. 4, d2 denotes a depth of the first trench 23, which is a dimension of the first trench 23 in the vertical direction z of the semiconductor body 100; d31 denotes a depth of the field electrode 31, which is a dimension of the field electrode 31 in the vertical direction z of the semiconductor body 100; w2 denotes a trench width of the first trench 23, which is the (shortest) lateral dimension of the first trench 23; w3 denotes a trench width of the second trench 33, which is the (shortest) lateral dimension of the second trench 33; s23 denotes a shortest distance between the first and second trenches 23, 33; and 111 denotes a length of the drift region 11, which is a dimension of the drift region 11 in the vertical direction z of the semiconductor body 100.

Referring to the above, the field electrode 31 extends at least as deep as the first trench 23 into the semiconductor body 100. Referring to FIG. 4, this includes that the depth d31 of the field electrode 31 equals at least the depth d2 of the first trench 23, d31≥d2. According to one example, the depth d31 of the field electrode is between 1.0 times and 2.5 times the depth d2 of the first trench 23, 1.0·d2≤d31≤2.5·d2. According to one example, the depth d31 of the field electrode is selected from between 0.8 micrometers (μm) and 2.5 micrometers.

According to one example, the trench width w2, w3 of each of the first and second trenches 23, 33 is selected from between 0.3 micrometers and 1.0 micrometer. The distance s23 between the first and second trenches 23, 33 may be selected from the same range as the trench widths w2, w3. That is, the distance s23 may be selected from between 0.3 micrometers and 1.0 micrometer.

According to one example, a (shortest) distance between two neighboring second trenches 33 in the region of the gate structure 2 is selected from between 0.5 micrometers and 2 micrometers. Given the trench width of between 0.3 micrometers and 1.0 micrometer this includes that in a device of the type illustrated in FIG. 1, the pitch p is between 0.8 (=0.5+2.0.15) micrometers and 3.0 (=2.0+2.0.5) micrometers. The pitch p is the center-to-center distance between two neighboring second trenches 33 are 2 neighboring first trenches 31, for example. As explained in detail herein further below, there are examples of the transistor device in which the distance between two neighboring second trenches 33 below the gate structure 2 is shorter than in the region of the gate structure 2.

The voltage blocking capability of the transistor device is, inter alia, dependent on the length 111 of the drift region 11. The length of the drift region 11 is essentially given by the (shortest) distance between the body regions 12 and the drain region 15. According to one example, the length 111 of the drift region is selected from between 5 micrometers and 30 micrometers. A SiC based transistor device can be implemented such that the voltage blocking capability essentially equals 100V per 1 μm length of the drift region (as compared to silicon, where the voltage blocking capability is only about 10V per 1 μm length of the drift region).

Referring to the above, the field electrodes 31, the source regions 13 and, optionally, the body regions 12 are connected to the source node S of the transistor device. Some examples for connecting the field electrodes 31, the source regions 13, and the body regions 12 to the source node S are explained in the following.

According to one example illustrated in FIG. 5, the transistor device includes a source metallization 41 on top of an insulating layer 43. The insulating layer 43 is formed on top of the first surface 100 of the semiconductor body 100 and electrically insulates the gate electrodes 21 from the source metallization 41. The source metallization 41 is connected to the source node S or forms the source node S of the transistor device. Furthermore, the transistor device includes electrically conducting vias 42 that extend through the insulating layer 43 and at least connect the field electrodes 31 to the source metallization 41 and that may also be referred to as source vias 42. “At least” in this context includes that the vias 42 connect the field electrodes 31 to the source metallization 41. Additionally, the source vias 42 may directly connect the source regions 13 to the source metallization 41. Alternatively, the source regions 13 may be connected to the field electrodes 31 (as explained herein further below) so that the source regions 13 are indirectly connected to the source metallization 41 through the vias 42.

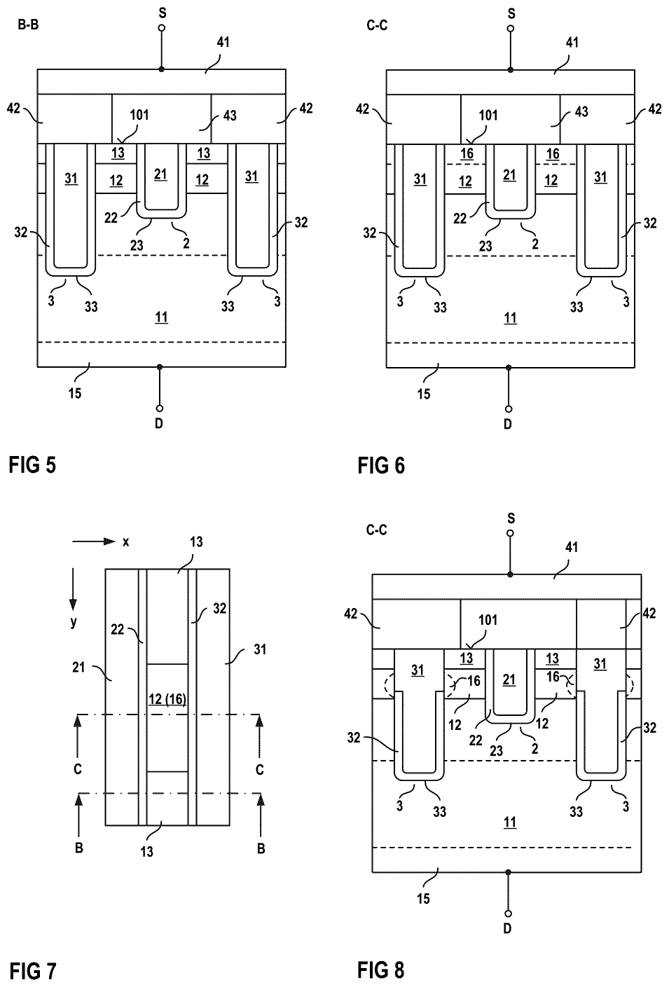

In order to connect the body regions 12 to the electrically conducting vias 42, sections of the body regions 12 may extend to the first surface 100 where they are connected to the electrically conducting vias 42. This is illustrated in FIG. 6, which shows a vertical cross-sectional view of the transistor device in a region in which sections of the body regions 12 extend to the first surface 101 of the semiconductor body. Optionally, the body region sections extending to the first surface 100 have a higher doping concentration than the remainder of the body regions in order to achieve an ohmic contact between the body regions 12 and the electrically conducting vias 42. Such higher doped contact regions are referenced with reference number 16 in FIG. 6.

FIG. 7 shows a horizontal cross-sectional view of a transistor device of the type illustrated in FIG. 6. In this transistor device, source regions 13 and body regions 12 are arranged alternatingly along the first surface 101 in a lateral direction y, so that alternatingly source and body regions 13, 12 are connected to the source via 42. A vertical cross-sectional view in vertical section plane B-B of the device illustrated in FIG. 7 corresponds to the vertical cross-sectional view illustrated in FIG. 5, and a vertical cross-sectional view in vertical section plane C-C of the device illustrated in FIG. 7 corresponds to the vertical cross-sectional view illustrated in FIG. 6.

FIG. 8 illustrates a vertical cross-sectional view of a portion of a transistor device according to another example. In this example, different from the examples illustrated in FIGS. 1, 5, and 6, the high-k dielectric 32 does not extend to the first surface 101 but terminates in the semiconductor body 100 spaced apart from the first surface 101, so that the field electrode 31 adjoins the source and body regions 13, 12 at sidewalls of the second trench 33 and is electrically connected to the source and body regions 13, 12. Optionally, a contact region 16 of the same doping type and more highly doped than the body region 12 is arranged between the field electrode 31 and the body region 12 in order to provide for an ohmic contact between the field electrode 13 and the body region 12. The source via 42 is connected to the field electrode 31, so that the source via 42 is connected to the source and body regions 13, 12 through the field electrode 31. As illustrated in the left section of FIG. 8, the source via 42 may further be connected to portions of the source region 13 along the first surface 101, so that the source via 42 is connected to the source region 13 both directly and through the field electrode 31. This, however, is only an example. As illustrated in the right section of FIG. 8 it is also possible that the source via 42 is only connected to the field electrode 31, so that the source via 42 is connected to the source region 13 only through the field electrode 31.

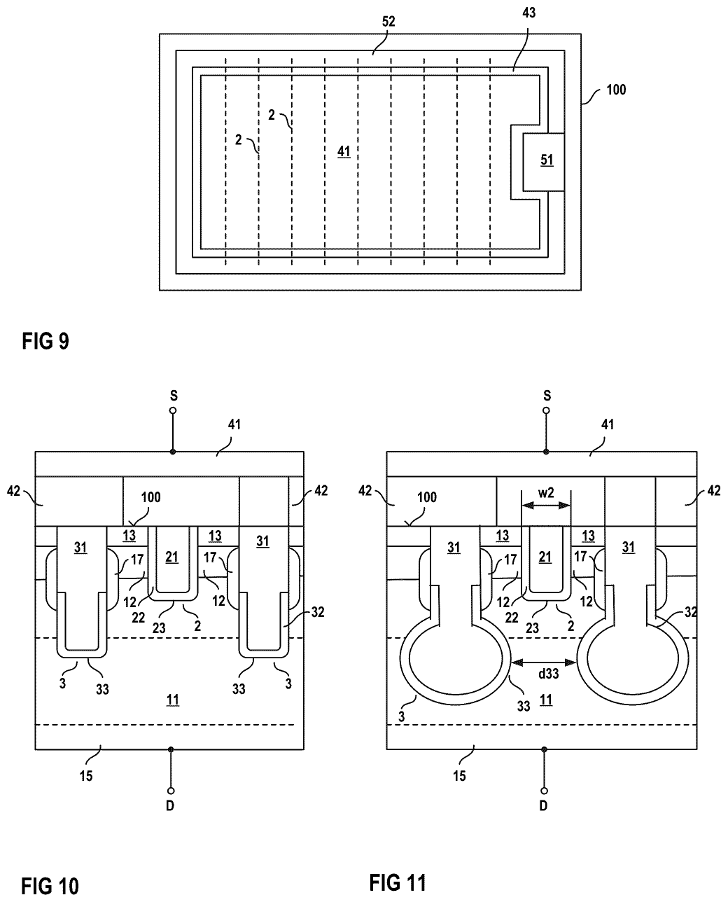

FIG. 9 shows a top view of the transistor device according to one example. More specifically, FIG. 9 shows a top view of the semiconductor body 100 with the source metallization 41. Examples of the gate structures 2 and their position below the source metallization 41 are illustrated in dashed lines in FIG. 9. In this example, the gate structures 2, below the source metallization 41, extend beyond the source metallization 41 and are connected to a gate runner 52. The gate runner 52 is formed on top of the insulating layer 43 and is connected to a gate pad 51. The gate pad 51 is connected to the gate node G or forms the gate node G of the transistor device.

The transistor device according to FIG. 9 includes only one source metallization 41. This, however, is only an example. According to another example (not illustrated) the transistor device includes several source metallizations that are each connected to the source node S and includes two or more gate runners 52 that are each connected to the gate pad 51.

FIGS. 10-13 illustrate further examples of transistor devices of the type illustrated in FIG. 1. Each of FIGS. 10-13 shows a vertical cross-sectional view of one portion of the transistor device.

The transistor device illustrated in FIG. 10 is based on the transistor device illustrated in FIG. 8 and is different from the transistor device illustrated in FIG. 8 in that the high-k dielectric 32 terminates spaced apart from the first surface 101 within the drift region 11. The drift region 11 is separated from the field electrode 31 by a doped region 17 of the same doping type as the body region 12 and more highly doped than the body region 12. According to one example, the doping concentration of the doped region 17 is at least 10 times, or at least 100 times the doping concentration of the body region 12.

According to one example, the doped region 17 not only separates the drift region 11 from the field electrode 31, but (as illustrated in FIG. 10) is also arranged between the field electrode 31 and at least a portion of the body region 12. In this example, the doped region 17 provides for an ohmic contact between the field electrode 31 and the body region 12.

Furthermore, the doped region 17 and the drift region 11 form a PN junction, so that in the blocking state of the transistor device a depletion region (space charge region) may expand in the drift region 11 beginning at the PN junction. Thus, the doped region 17, in addition to the field electrode structure 3 with the field electrode 31 and the high-k dielectric 32 may support a depletion of the drift region 11 around the gate dielectric 22 and, therefore, helps to protect the gate dielectric 22 against high electric fields in the blocking state of the transistor device. According to one example, the doping concentration of the doped region 17 is high enough that the depletion region 17, in the blocking state of the transistor device, cannot be completely depleted of charge carriers.

Referring to FIG. 10, the doped region 17 may overlap the high-k dielectric 32. Furthermore, according to one example, the doped region 17, in the vertical direction z, extends deeper than the first trench 23 with the gate electrodes 21 and the gate dielectric 22.

FIG. 11 shows a modification of the transistor device according to FIG. 10. In the example illustrated in FIG. 11, the field electrode trenches 33 are implemented such that field electrode trenches 33 widen below bottoms of the first trench 23, so that neighboring second trenches 33 form a kind of bottleneck in the drift region 11 below the gate trench 23 with the gate electrode 21 and the gate dielectric 22. According to one example, the second trenches are implemented such that a shortest distance d33 between two neighboring second trenches 33 in the lateral direction is between 0.5 times and 2 times the trench width w2 of the first trench 23.

Narrowing the drift region 11 due to the widening field electrode trenches 33, in the blocking state of the transistor device, helps to deplete the drift region 11 in the region around the gate dielectric 22 and, therefore, helps to protect the gate dielectric 22 against high electric fields.

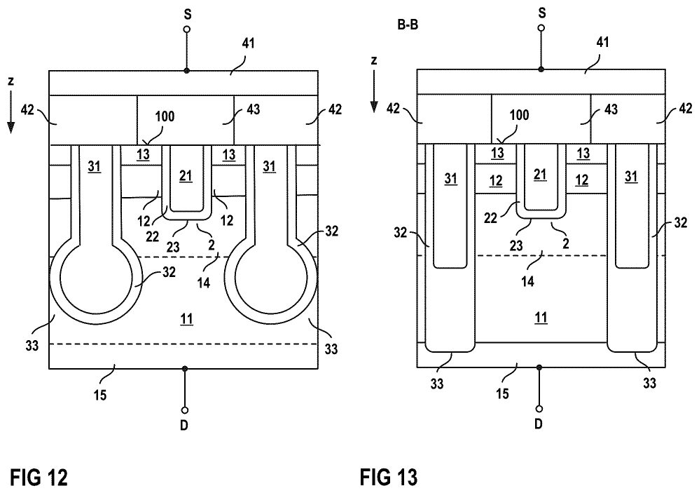

It should be noted that implementing the transistor device with widened field electrode trenches 33 of the type illustrated in FIG. 11 is not restricted to the specific implementation shown in FIG. 11 in which the high-k dielectric 32 terminates in the drift region 11 and in which the field electrode 31 is separated from the drift region 11 by the doped region 17. Instead, widened field electrode trenches 33 may also be used in a transistor device in which the high-k dielectric 32 extends to the first surface 101. A transistor device of this type is illustrated in FIG. 12.

According to another example (not illustrated) widened field electrode trenches 33 are implemented in a transistor device of the type illustrated in FIG. 8 in which the high-k dielectric 32 terminates spaced apart from the first surface 101 in the body region 12.

FIG. 13 shows a transistor device according to another example. In this example, the field electrode trenches 33, in the vertical direction z, extend into the drain regions 15. The dimension of the field electrodes 31 can be as explained hereinabove. Sections of the second trenches 33 between lower ends of the field electrodes 31 and bottoms of the second trenches 33 are filled with a dielectric. According to one example, the dielectric between the lower ends of the field electrodes 31 and the bottoms of the second trenches 33 is a high-k dielectric of the same type as the high-k dielectric separating the field electrode 31 from the drift region 11.

In the transistor device according to FIG. 13, due to the high-k dielectric arranged in the field electrode trenches 33 between the bottoms of the field electrodes 31 and the bottoms of the field electrode trenches 33, an effective dielectric constant of the drift region 11 is higher than in a transistor device that is devoid of such high-k dielectric in the drift region 11 between the field electrodes 31 and the drain region 15. Due to the increased dielectric constant, the drift region 11 can be implemented with a higher doping concentration, so that the transistor device has a lower on-resistance, without reducing the voltage blocking capability.

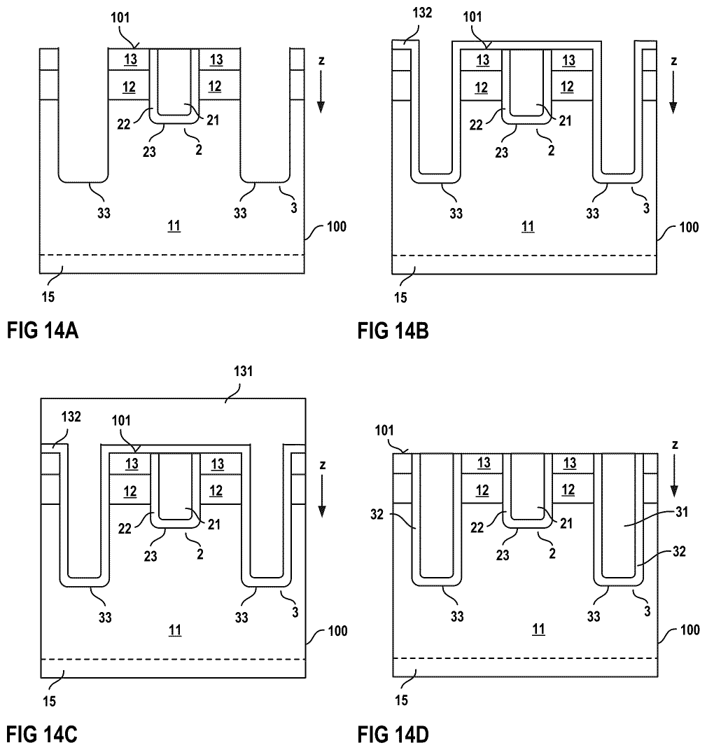

FIGS. 14A-14D illustrate one example of a method for forming a transistor device of the type illustrated in FIG. 1. More specifically, FIGS. 14A-14D show vertical cross-sectional views of one portion of the semiconductor body 100 during different process sequences. The portion of the semiconductor body 100 illustrated in FIGS. 14A-14D includes one gate trench 23 arranged between two neighboring field electrode trenches 33. It should be noted that the process sequences illustrated in FIGS. 14A-14D as well as process sequences explained herein further below may take place on a wafer level. That is, a plurality of transistor devices can be formed on a wafer at the same time, wherein the wafer is finally subdivided into the individual transistor devices.

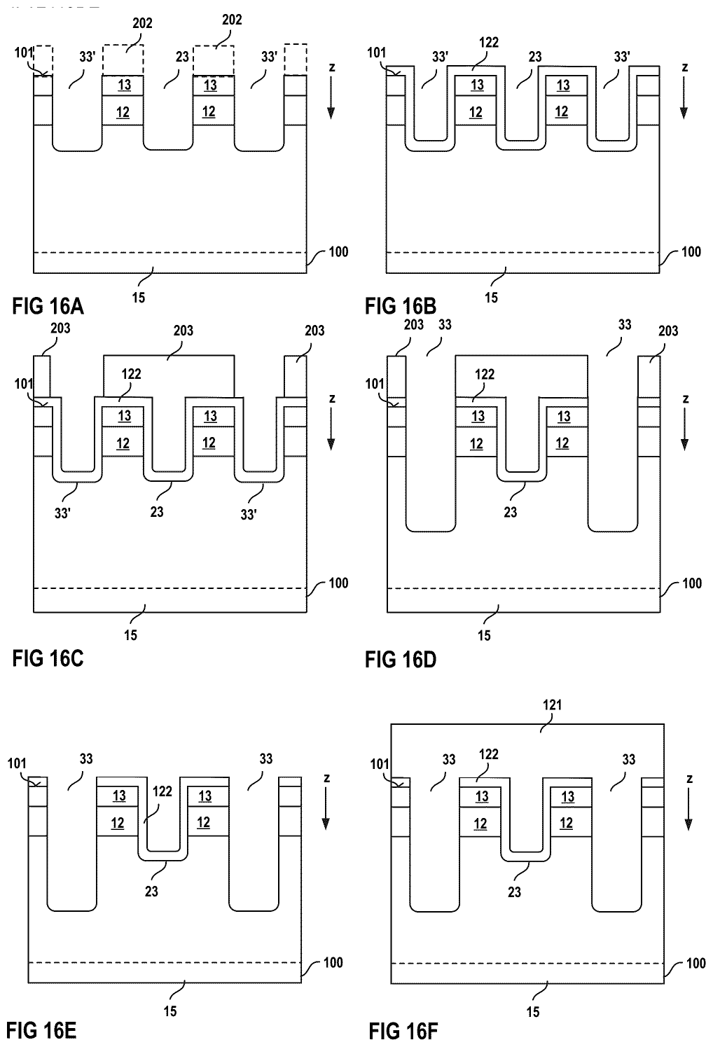

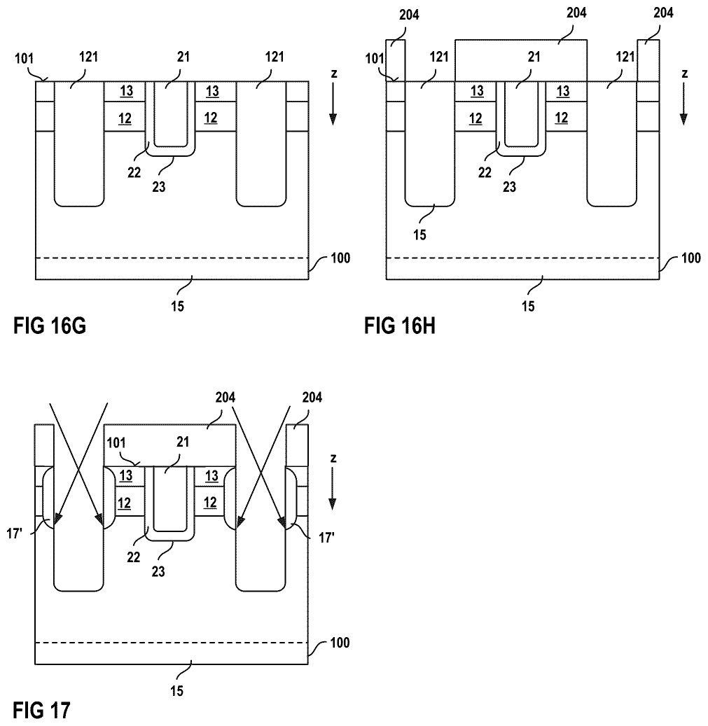

FIG. 14A shows the semiconductor body 100 after forming the gate structures 2 and after forming the field electrode trenches 33. One example for forming the gate structures 2 and the field electrode trenches 33 is explained with reference to FIGS. 16A-16H herein further below. According to one example, the gate structures 2 and the field electrode trenches 33 are formed after forming the doped regions that form the source and body regions 13, 12 in the finished transistor device. Forming these doped regions may include an implantation process in which dopant atoms are implanted into the semiconductor body 100 through the first surface 101.

Referring to FIG. 14B, the method includes forming a high-k dielectric layer 132. In the finished device, portions of the high-k dielectric layer 132 form the high-k dielectric 32 in the field electrode trenches 33. Referring to FIG. 14B, forming the high-k dielectric layer 132 may include depositing the high-k dielectric layer 132 such that the high-k dielectric layer 132 covers surfaces (sidewalls and bottoms) of the field electrode trenches 33 and covers the first surface 101 of the semiconductor body 100 and the gate structure 2.

Referring to FIG. 14C, the method further includes forming a field electrode layer 131. In the finished device, portions of the field electrode layer 131 form the field electrodes 31 in the field electrode trenches 33. Referring to FIG. 14C, forming the field electrode layer 131 may include depositing the field electrode layer 131 such that the field electrode layer 131 fills the field electrode trenches 33 on top of the high-k dielectric layer 132 and covers the high-k dielectric layer 132 on top of the first surface 101 of the semiconductor body 100 and on top of the gate structures 2.

Referring to FIG. 14D, the method further includes removing the field electrode layer 131 and the high-k dielectric layer 132 from on top of the first surface 101, so that the high-k dielectric layer 132 remains in the field electrode trenches 33 where it forms the high-k dielectric 32 and so that the field electrode layer 131 remains in the field electrode trenches 33 on top of the high-k dielectric 32 where it forms the field electrodes 31. Removing the field electrode layer 131 and the high-k dielectric layer 132 from above the first surface 101 may include at least one of an etching process, a polishing process, such as a CMP (chemical mechanical polishing) process, or the like.

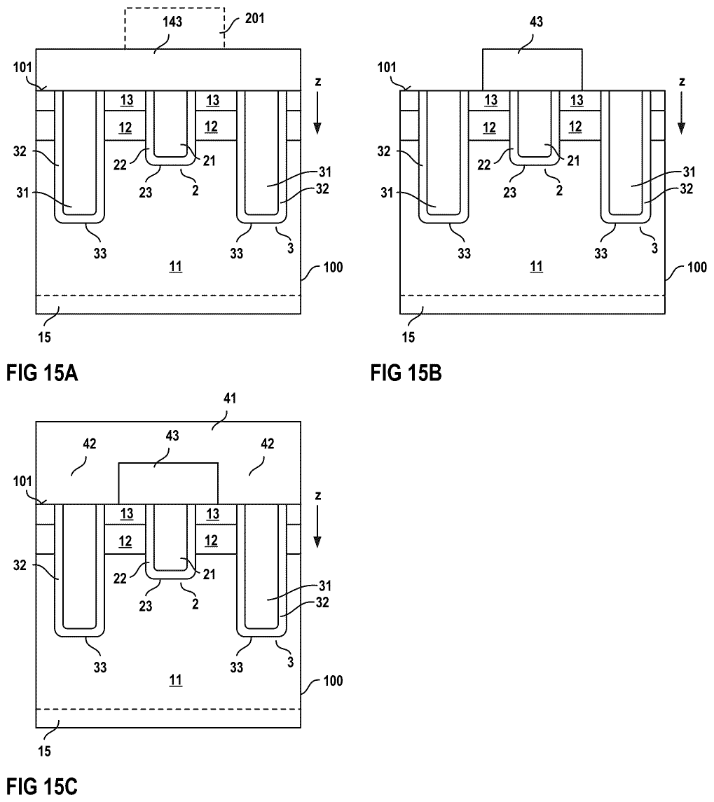

FIGS. 15A-15C illustrate one example of a method for forming the insulating layer 43 on top of the gate structure 2, the source metallization 41, and the source vias 42. Referring to FIGS. 15A-15B the method includes forming the insulating layer 43 such that the insulating layer 43 covers the gate structure 2 in those regions of the semiconductor body 100 on top of which the source metallization 41 is formed. Forming the insulating layer 43 may include depositing an insulating layer 143 that covers the entire first surface 101, and patterning the deposited insulating layer 143 such that the gate structures 2 are covered and at least portions of the field electrodes 31 are not covered. Patterning the deposited insulating layer may include an etching process using an etch mask 201 (that is illustrated in dashed lines in FIG. 15A).

Just for the purpose of illustration, in the example shown in FIG. 15B, the insulating layer 43 is formed such that not only portions of the field electrodes 31 but also portions of the source regions 13 are not covered by the insulating layer 43. This, however, is only an example. It is also possible to form the insulating layer 43 such that it entirely covers the source regions 13. In this example, the source regions 13 are connected to the source metallization 41 in the finished device through the field electrodes 31 as illustrated in FIGS. 8, 10, and 11, for example.

Referring to FIG. 15C, the method further includes forming the source metallization 41 and the source vias 42. This may include one process step in which a metal layer is deposited on top of the insulating layer 43 and those sections of the first surface 101 not covered by the insulating layer 43. In this example, the metal layer, at the same time, forms the first metallization 41 and the source vias 42.

FIGS. 16A-16H illustrate one example of a method for forming gate structures 2 and second trenches 33 of the type illustrated in FIG. 14A. Each of FIGS. 16A-16H shows a vertical cross-sectional view of one portion of the semiconductor body 100 during different process sequences.

Referring to FIGS. 16A, the method includes forming the gate trenches 23 and forming partial field electrode trenches 33′ by the same etching process. Forming these trenches 23, 33′ may include an anisotropic etching process using an etch mask 202 (illustrated in dashed lines in FIG. 16A) formed on top of the first surface 101.

Referring to FIG. 16B the method further includes forming a gate dielectric layer 122. Portions of the gate dielectric layer 122 form the gate dielectrics 22 in the finished transistor device. Forming the gate dielectric layer 122 may include depositing the gate dielectric layer 122 to cover surfaces (bottoms and sidewalls) of the gate trenches 23 and of the partial field electrode trenches 33′ and to cover the first surface 101 of the semiconductor body 100. The material of the gate dielectric layer 122 corresponds to the desired material of the gate dielectric 22.

Referring to FIGS. 16C and 16D the method further includes removing the gate dielectric layer 122 from the partial field electrode trenches 33′ and etching the partial field electrode trenches 33′ deeper into the semiconductor body 100 to form the field electrode trenches 33.

Referring to FIG. 16C, removing the gate dielectric layer 122 from the partial field electrode trenches 33′ may include forming a protection layer 203. The protection layer 203 covers those sections of the gate dielectric layer 122 that remain and does not cover those sections of the gate dielectric layer 122 that are to be removed. The protection layer 203 comprises a photoresist, for example, and may be patterned using a conventional lithographic process. Those sections of the gate dielectric layer 122 that are not covered by the protection layer 203 may be removed using an etching process, for example.

Further extending the partial field electrode trenches 33′ into the semiconductor body 100 to form the field electrode trenches 33 may include an etching process. According to one example the protection layer 203 used in the process of partially removing the gate dielectric layer 122 is used as an etch mask in the process of etching the partial field electrode trenches 33′ deeper into the semiconductor body. This, however, is only an example. It is also possible to use an etch mask that is different from the protection layer.

After forming the field electrode trenches 33, the protection layer 203 is removed. FIG. 16E shows the semiconductor body 100 after removing the protection layer 23.

The method further includes forming the gate electrodes 21 in the gate trenches 23 on top of the gate dielectric 22. Referring to FIG. 16F this may include depositing a gate electrode layer 121 over the entire arrangement, so that the gate electrode layer 121 fills the field electrode trenches 33, fills the gate trenches 23 on top of the gate dielectric layer 122, and is formed above the first surface 101 of the semiconductor body 100.

Referring to FIG. 16G, the method further comprises a planarizing process in which the gate electrode layer 121 and in which portions of the gate dielectric layer 102 formed on top of the first surface 101 of the semiconductor body 100 are removed. The planarizing process may include at least one of an etching process and a polishing process. Those sections of the gate dielectric layer 122 that remain in the gate trenches 23 after the planarizing process form the gate dielectrics 22. Furthermore, those sections of the gate electrode layer 121 that remain on top of the gate dielectrics 22 in the gate trenches 23 form the gate electrodes 21.

The method further includes removing the gate electrode layer 121 from the field electrode trenches. This may include an etching process using an etch mask 204 that covers the first surface 101 of the semiconductor body 100. The semiconductor body 100 with the etch mask 204 and before the etching process is illustrated in FIG. 16H. Removing the gate electrode layer 121 from the field electrode trenches 23 in the etching process results in the arrangement illustrated in FIG. 14A.

FIG. 17 illustrates one example of a method for forming a doped region 17 of the type explained with reference to FIG. 10. Referring to FIG. 17 forming the doped region 17 may include a tilted implantation process in which dopant atoms are implanted into sidewalls of the gate trenches to form implanted regions 17′. The implanted regions 17′ define the size and position of the doped regions 17, wherein forming the doped region 17 based on the implanted regions 17′ includes an annealing process.

Referring to FIG. 17, an implantation mask may be formed on top of the first surface 101 to prevent dopant atoms from being implanted into the first surface 101. The implantation mask may be the same mask as the etch mask 204 used in the method explained with reference to FIG. 16H.

In the process illustrated in FIG. 17, the implanted regions 17′, in the vertical direction z essentially extend to the first surface 101. In this example, the source regions 13 are separated from the doped region 17 from the field electrode 31. Thus, in this example, the source regions 13 are connected to the source vias 42 at the first surface 101 in the way illustrated in FIG. 5, for example.

Doped regions 17 of the type illustrated in FIG. 10, which are spaced apart from the first surface 101, may be implemented in various ways. According to one example, forming these regions 17 includes a first tilted implantation process of the type illustrated in FIG. 17 that forms implanted regions 17′ which extend to the first surface 101. In addition to this first tilted implantation process in which dopant atoms of the second doping type are implanted, forming the doped regions 17 may include a second tilted implantation process in which dopant atoms of the first doping type are implanted into the trench sidewalls in regions adjoining the first surface 101. The implantation dose in the second tilted implantation process may be equal to the implantation dose in the first tilted implantation process, so that in the regions adjoining the first surface 101 the two tilted implantation processes result in an effective doping concentration of zero and doped regions 17 of the second doping type spaced apart from the first surface 101 are formed.

According to another example, a doped region 17 of the second doping type is formed in the semiconductor body 100 in a region spaced apart from the first surface 101 before forming the field electrode trenches 33. Forming the dopant region of the second doping type may include an implantation process. The field electrode trenches 33 are then formed to partially remove such doped regions of the second doping type, wherein remainders of the dopant region formed before forming the field electrode trenches 33 form the doped regions 17.

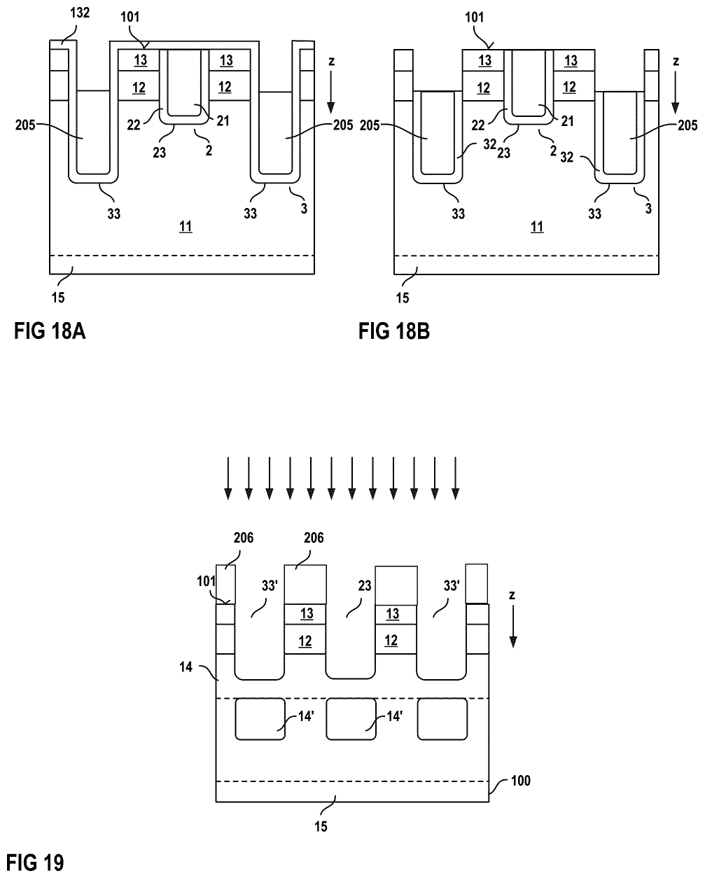

FIGS. 18A-18B illustrate one example of a method for forming a recessed high-k dielectric 32, which is a high-k dielectric that terminates spaced apart from the first surface 101 of the semiconductor body 100. Referring to FIG. 18A, the method, after forming the high-k dielectric layer 132 includes forming a protection layer 205 on top of those sections of the high-k dielectric layer 132 that should remain in the field electrode trenches 33. Forming the protection layer 205 may include depositing a protection layer all over the semiconductor body 100 and etching back the protection layer such that the protection layer 205 only remains in the field electrode trenches 33 in those sections in which the high-k dielectric layer 132 is to be covered.

Referring to FIG. 18B, the method further includes removing the high-k dielectric layer 132 in those sections not covered by the protection layer 205. Removing the high-k dielectric layer 132 may include an etching process that etches the high-k dielectric layer 132 selectively relative to the semiconductor body 100. Finally, the protection layer 205 may be removed. Removing the protection layer 25 may include an etching process that etches the protection layer 25 selectively relative to the semiconductor body 100 and the high-k dielectric 32.

Referring to the above, the transistor device may include a current spreading region 14 in the drift region 11 that helps to more equally distribute the current (charge carriers) within the drift region 11 that is injected by the channel regions along the gate dielectric 22 into the drift region 11. Forming the current spreading region 14 may include an implantation process in which dopant atoms are implanted into the drift region 11 via the first surface 101, and an annealing process in which the implanted dopant atoms are activated. Alternatively, the current spreading region 14 is formed in an epitaxial growth process during the crystal growth of the semiconductor body 100.

Alternatively or additionally to implanting dopant atoms via the first surface 101 dopant atoms may be implanted into the drift region 11 via bottoms of the gate trenches 23 and the partial field electrode trenches 33′ formed in the process explained with reference to FIG. 16A. FIG. 19 illustrates one example of a process in which dopant atoms are implanted in the drift region 11 via bottoms of the gate trenches 23 and the partial field electrode trenches 33′. An implantation mask 206 formed on top of the first surface 101 protects the first surface 101 from having dopant atoms implanted therein.

Implanting the dopant atoms forms implanted regions 14′ in the drift region 11 below the bottoms of the trenches 23, 33′. By suitably adjusting the implantation energy, the implanted regions 14′ can be formed to adjoin the trenches or can be formed to be spaced apart from the trenches 23, 33′. Forming the current spreading region 14 based on the implanted regions 14′ includes an annealing process.

According to one example, as illustrated, the dopant atoms are implanted only into the bottoms of the trenches 23, 33′. In this example, several implanted regions 14′ are formed that are spaced apart from each other in the lateral direction of the semiconductor body 100. In SiC there is no significant diffusion of implanted dopant atoms in an annealing process. Thus, in this example, the transistor device includes a plurality of current spreading regions 14 that are spaced apart from each other in the lateral direction.

According to another example, a tilted implantation process is used to form the implanted regions 14′. In this example, the implanted regions 14′ can be formed such that neighboring implanted regions 14′ adjoin one another. In this example, a contiguous current spreading region is formed after the annealing process.

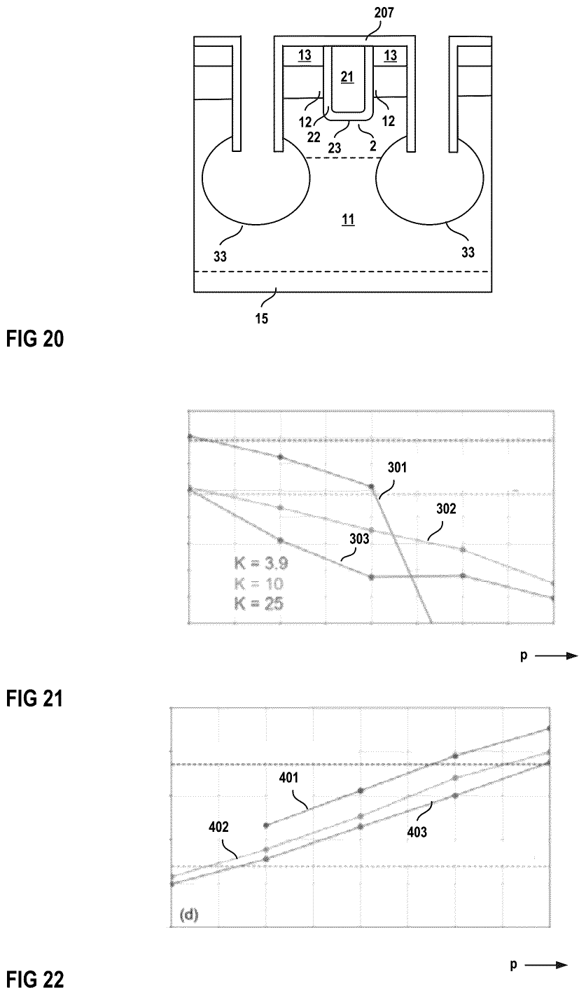

FIG. 20 illustrates one example of a method for forming field electrode trenches 33 that widen below the gate trenches 23. Forming each of these trenches may include forming a partial trench using a conventional anisotropic etching process, covering sidewalls of the first partial trench with a protection layer 207 and leaving a bottom of the trench uncovered by the protection layer 207, and performing an isotropic etching process that etches the trench in the vertical direction and in lateral directions deeper into the semiconductor body 100.

FIG. 21 illustrates the voltage blocking capability of different transistor devices that are implemented in the same way and are only different in view of the dielectric constant of the high-k dielectric 32 and the cell pitch p. For comparison reasons, curve 301 illustrates the voltage blocking capability dependent on the cell pitch p in a transistor device implemented with a low-k dielectric as the field electrode dielectric. In the present example, the low-k dielectric is silicon dioxide (SiO₂) having a relative dielectric constant of 3.9.

Curve 302 illustrates the voltage blocking capability dependent on the cell pitch p in a transistor device implemented with a high-k dielectric 32 having a relative dielectric constant of 10, and curve 303 illustrates the voltage blocking capability in a transistor device implemented with a high-k dielectric 32 having a relative dielectric constant of 25.

As can be seen from FIG. 21, in each case, the voltage blocking capability decreases as the pitch p increases. Furthermore, the voltage blocking capability of transistor devices implemented with the low-k dielectric dramatically decreases below the voltage blocking capability of transistor devices with the same pitch but implemented with a high-k dielectric. In each case, the breakdown occurs below the field electrode trenches 33.

FIG. 22, illustrates the magnitude of the electric field in the gate dielectrics 22 of the same transistor devices as illustrated in FIG. 21 dependent on the cell pitch p. Curve 401 represents the transistor devices implemented with the low-k dielectric, curve 402 represents the transistor devices implemented with the high-k dielectric having the dielectric constant of K=10, and curve 403 represents the transistor devices implemented with the high-k dielectric having the dielectric constant of K=25. As can be seen from FIG. 22, in each case, the electric field increases as the pitch p increases. Furthermore, at each pitch, the lower the dielectric constant, the higher the electric field.

Thus, based on FIGS. 21 and 22 it can be seen that in the transistor device according to FIG. 1 and its various modifications explained herein a high voltage blocking capability can be achieved by implementing the transistor device with field electrode structures 3 that each include a field electrode 31 and a high-k dielectric 32.

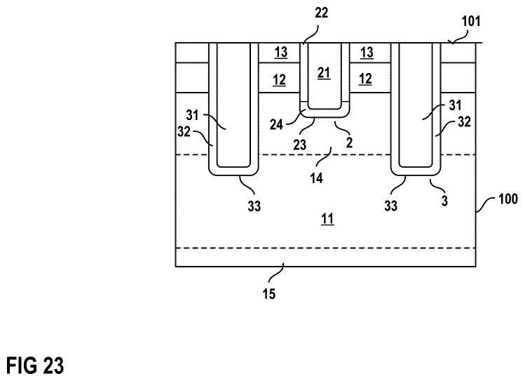

FIG. 23 shows a modification of the transistor device according to FIG. 1. In this example, each of the gate trenches 23 includes two different dielectrics, the gate dielectric 22 between the gate electrode 21 and the body region 21, the source region 13, and a portion of the drift region 11, and a high-k dielectric 24 at the bottom of the gate trench 23 between the gate electrode 21 and the drift region 11. The high-k dielectric 24 is more robust in view of high electric fields than the gate dielectric 22.

Some aspects of the transistor device and the method explained above are briefly summarized in the following.

According to one example, the transistor device includes a semiconductor body and a plurality of transistor cells. Each transistor cell includes a drift region, a body region, and a source region; a gate electrode connected to a gate node; and a field electrode connected to a source node. The gate electrode is dielectrically insulated from the body region by a gate dielectric, and is arranged in a first trench extending from a first surface into the semiconductor body. The field electrode is dielectrically insulated from the drift region by a high-k dielectric, and is arranged in a second trench. The second trench extends from the first surface into the semiconductor body and is spaced apart from the first trench, and the field electrode extends at least as deep as the first trench into the semiconductor body.

The field electrode may extend deeper than the first trench into the semiconductor body. The field electrode may be dielectrically insulated from the body region and the source region by the high-k dielectric. The field electrode may be electrically connected to the body region and the source region in the second trench.

Each transistor cell may include a doped region of the same doping type as the body region, wherein the doped region adjoins the body region and the field electrode and extends along the high-k dielectric into the drift region.

The transistor device may further include a source electrode electrically connected to the field electrodes, the source regions, and the body regions of the plurality of transistor cells, wherein the source electrode is connected to the source node or forms the source node of the transistor device. The transistor device may further include a drain region, wherein each of the drift regions of the plurality of transistor cells is arranged between the body region of the respective transistor cell and the drain region.

Each transistor cell may include a current spreading region in the drift region, wherein the current spreading region is more highly doped then a remainder of the drift region.

According to one example, the second trenches of the plurality of transistor cells are spaced apart from the drain region. According to another example, the second trenches of the plurality of transistor cells, along the drift regions, extend into the drain region.

According to one example, the first trenches are implemented such that in a region below a first trench arranged between two neighboring second trenches, a distance between the neighboring second trenches is shorter than in a region of the first trench.

A relative dielectric constant of the high-k dielectric may be higher than the relative dielectric constant of silicon dioxide. According to one example, the relative dielectric constant is higher than 5, higher than 10, or higher than 20.

According to one example, a dimension of the field electrode in a vertical direction of the semiconductor body is between 1.0 times and 2.5 times a depth of the first trench. A dimension of the field electrode in a vertical direction of the semiconductor body is between 0.8 micrometers and 2.5 micrometers, for example. A distance between neighboring second trenches is between 0.5 micrometers and 2 micrometers, for example.

According to one example, the semiconductor body is a SiC semiconductor body.

According to another example, a method for forming a transistor device includes forming a plurality of transistor cells in a semiconductor body such that each transistor cell includes a drift region, a body region, and a source region; a gate electrode connected to a gate node, dielectrically insulated from the body region by a gate dielectric, and arranged in a first trench extending from a first surface into the semiconductor body; and a field electrode connected to a source node, dielectrically insulated from the drift region by a high-k dielectric, and arranged in a second trench extending from the first surface into the semiconductor body and spaced apart from the first trench. Forming the field electrode of each transistor cell includes forming the field electrode such that the field electrode extends deeper into the semiconductor body than the first trench.

According to one example, the field electrodes are formed after forming the gate dielectrics and the gate electrodes.

1. A transistor device comprising a semiconductor body and a plurality of transistor cells, wherein each transistor cell comprises:
a drift region;
a body region;
a source region;
a gate electrode connected to a gate node; and
a field electrode connected to a source node,
wherein the gate electrode is dielectrically insulated from the body region by a gate dielectric, and is arranged in a first trench extending from a first surface into the semiconductor body,
wherein the field electrode is dielectrically insulated from the drift region by a high-k dielectric, and is arranged in a second trench,
wherein the second trench extends from the first surface into the semiconductor body and is spaced apart from the first trench, and
wherein the field electrode extends at least as deep as the first trench into the semiconductor body.

2. The transistor device of claim 1,
wherein the field electrode extends deeper than the first trench into the semiconductor body.

3. The transistor device of claim 1,
wherein the field electrode is dielectrically insulated from the body region and the source region by the high-k dielectric.

4. The transistor device of claim 1,
wherein the field electrode is connected to the body region and the source region in the second trench.

5. The transistor device of claim 4, wherein each transistor cell further comprises:
a doped region of the same doping type as the body region,
wherein the doped region adjoins the body region and the field electrode and extends along the high-k dielectric into the drift region.

6. The transistor device of claim 1, further comprising:
a source electrode connected to the field electrode, the source region, and the body region,
wherein the source electrode is connected to the source node or forms the source node.

7. The transistor device of claim 1, further comprising:
a drain region,
wherein the drift region is arranged between the body region and the drain region.

8. The transistor device of claim 1, wherein each transistor cell further comprises:
a current spreading region in the drift region, wherein the current spreading region is more highly doped then a remainder of the drift region.

9. The transistor device of claim 7,
wherein the second trench is spaced apart from the drain region.

10. The transistor device of claim 7,
wherein the second trench, along the drift region, extends into the drain region.

11. The transistor device of claim 1,
wherein, in a region below a third trench arranged between two neighboring trenches, a distance between the neighboring trenches is shorter than in a region of the first trench.

12. The transistor device of claim 1, wherein a relative dielectric constant of the high-k dielectric is higher than the relative dielectric constant of silicon dioxide.

13. The transistor device of claim 12, wherein the relative dielectric constant of the high-k dielectric is higher than 5.

14. The transistor device of claim 1, wherein a dimension of the field electrode in a vertical direction of the semiconductor body is between 1.0 times and 2.5 times a depth of the first trench.

15. The transistor device of claim 1, wherein a dimension of the field electrode in a vertical direction of the semiconductor body is between 0.8 micrometers and 2.5 micrometers.

16. The transistor device of claim 1, wherein a distance between neighboring second trenches is between 0.5 micrometers and 2 micrometers.

17. The transistor device of claim 1, wherein the semiconductor body is a SiC semiconductor body.

18. A method, comprising:
forming a plurality of transistor cells in a semiconductor body such that a transistor cell of the plurality of transistor cells comprises:
a drift region;
a body region;
a source region;
a gate electrode connected to a gate node, dielectrically insulated from the body region by a gate dielectric, and arranged in a first trench extending from a first surface into the semiconductor body; and
a field electrode connected to a source node, dielectrically insulated from the drift region by a high-k dielectric, and arranged in a second trench extending from the first surface into the semiconductor body and spaced apart from the first trench,
wherein forming the field electrode of each transistor cell includes forming the field electrode such that the field electrode extends deeper into the semiconductor body than the first trench.

19. The method of claim 18,
wherein the field electrode is formed after forming the gate dielectric and the gate electrode.

20. A transistor cell comprising:
a drift region;
a body region;
a source region;
a gate electrode connected to a gate node; and
a field electrode connected to a source node,
wherein the gate electrode is dielectrically insulated from the body region by a gate dielectric, and is arranged in a first trench extending from a first surface into a semiconductor body,
wherein the field electrode is dielectrically insulated from the drift region by a high-k dielectric, and is arranged in a second trench, and
wherein the second trench extends from the first surface into the semiconductor body and is spaced apart from the first trench.
